(19) United States
(12) Patent Application Publication
(10) Pub. No.: US 2026/0277115 A1
(43) Pub. Date: Sep. 17, 2026

(54) LITHOGRAPHY EXPOSURE SYSTEM AND LITHOGRAPHY METHOD USING THE SAME

(71) Applicant: TAIWAN SEMICONDUCTOR MANUFACTURING COMPANY, LTD., Hsinchu (TW)

(72) Inventors: Hui Ling CHEN, Tainan City (TW); Yen Wei CHEN, Tainan City (TW); Jih Hsing CHANG, Tainan City (TW); Chien Liang LIN, Tainan City (TW); Tzu Hsien WU, Tainan City (TW); Yen Ting CHEN, Taichung City (TW); Min Hsiang HSU, Taoyuan City (TW)

(73) Assignee: TAIWAN SEMICONDUCTOR MANUFACTURING COMPANY, LTD., Hsinchu (TW)

(21) Appl. No.: 19/076,377

(22) Filed: Mar. 11, 2025

(51) Int. Cl. G03F 7/00; G03F 1/72

(52) U.S. Cl. CPC G03F 7/70533; G03F 1/72; G03F 7/70508; G03F 7/7075

(57) ABSTRACT

A method includes securing a photomask to a mask stage of a lithography exposure system. A lithography process is performed to a semiconductor wafer by using the photomask and the lithography exposure system. If the photomask is qualified is determined by a control device of the lithography exposure system. If the semiconductor wafer is transported to a next process station is determined according to a determined result of the control device.

### BACKGROUND

In the semiconductor integrated circuit (IC) industry, technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of IC processing and manufacturing.

In a process of manufacturing the IC devices, a lithography process is employed to form a circuit pattern on a wafer. In the lithography process, a photomask is used to transfer a desired pattern onto the wafer. When the photomask is contaminated with foreign materials, such as particles, from the ambient environment, defects may occur on the wafer to which the pattern of the photomask is transferred.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic and diagrammatic view of a lithography exposure system 10 in accordance with some embodiments.

FIG. 2 is a flowchart illustrating a method of lithography processes in accordance with some embodiments.

FIG. 3 is a flowchart illustrating the operation S18 of the method of lithography processes in accordance with some embodiments.

FIG. 4 is a process for operation S18 by using the control device in accordance with some embodiments.

FIG. 5 is an illustrative diagram of the lithography exposure system, a conveyer system, the semiconductor wafers, a mask inspection tool, and a process station in accordance with some embodiments.

FIG. 6 is a block diagram illustrating an example of a computer system in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

Photolithographic patterning processes use a photomask that includes a desired mask pattern. The photomask may be a reflective mask or a transmission mask. In the process, ultraviolet light is reflected off the surface of the photomask (for a reflective mask) or transmitted through the photomask (for a transmission mask) to transfer the pattern to a photoresist layer on a semiconductor wafer. The exposed portion of the photoresist layer is photochemically modified. After the exposure, the photoresist layer is developed to define openings in the photoresist layer, and one or more semiconductor processing operations (e.g., etching, epitaxial layer deposition, metallization, etc.) are performed which operate on those areas of the wafer surface exposed by the openings in the photoresist layer. After this semiconductor processing, the photoresist layer is removed by a suitable resist stripper or the like.

The minimum feature size of the pattern is limited by the light wavelength. Deep ultraviolet (UV) lithography, for example using a wavelength of 193 nm or 248 nm in some standard deep UV platforms, typically employs transmission masks and provides a smaller minimum feature size than lithography at longer wavelengths. Extreme ultraviolet (EUV) light, which spans wavelengths from 124 nm down to 10 nm, is currently being used to provide even smaller minimum feature size. At shorter wavelengths, particle contaminants on the photomask can cause defects in the transferred pattern.

Some embodiments of the present disclosure are related to lithography exposure systems and methods for ranking photomasks based on their qualities during lithography (or exposure) processes. More specifically, some embodiments of the present disclosure are related to dynamic ranking the photomasks during the exposure processes. Once the photomasks with qualified qualities are in use, the semiconductor wafers exposed by using the qualified photomasks may go to the next process stations without waiting for mask inspections, thereby reducing the cycle time of the semiconductor wafers.

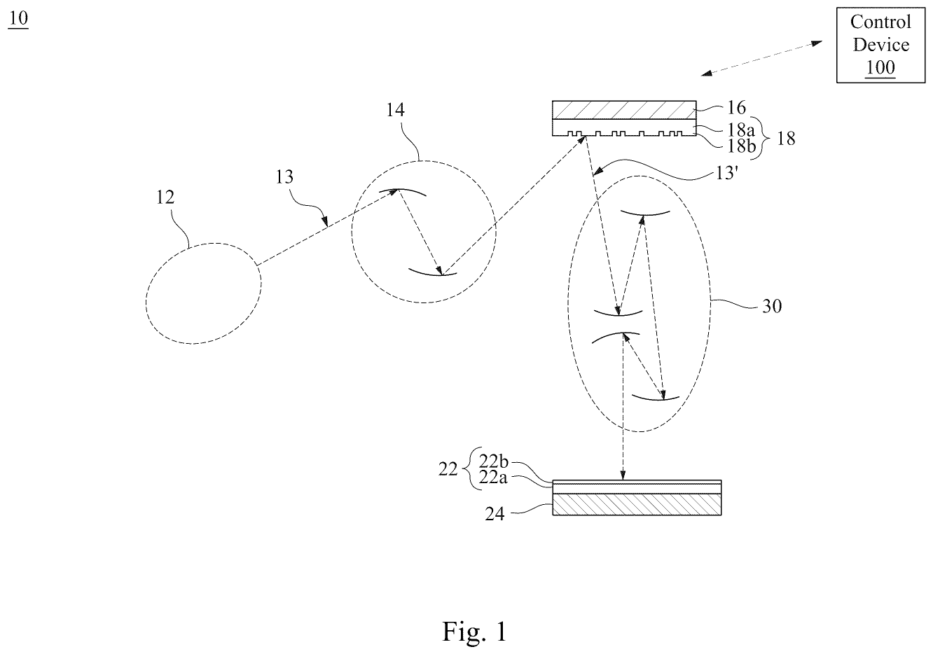

FIG. 1 is a schematic and diagrammatic view of a lithography exposure system 10, in accordance with some embodiments. In some embodiments, the lithography exposure system 10 is an extreme ultraviolet (EUV) lithography system designed to expose a photoresist layer by EUV radiation, and may also be referred to as the EUV system. The EUV system may also be referred to as an EUV scanner or lithography scanner. In some other embodiments, the lithography exposure system 10 is a deep ultraviolet lithography system, an immersion lithography system, or other suitable lithography systems. The lithography exposure system 10 includes a light source 12, an illuminator 14, a mask stage 16, a projection optics module (or projection optics box (POB)) 30 and a substrate stage 24, in accordance with some embodiments. The elements of the lithography exposure system 10 can be added to or omitted, and the disclosure should not be limited by the embodiment.

The light source 12 is configured to generate radiation (or light) 13 having a wavelength ranging between about 1 nm and about 100 nm in certain embodiments. In one particular example, the light source 12 generates an EUV radiation with a wavelength centered at about 13.5 nm. Accordingly, the light source 12 is also referred to as an EUV radiation source. However, it should be appreciated that the light source 12 should not be limited to emitting EUV radiation. The light source 12 can be utilized to perform any high-intensity photon emission from excited target fuel. In some embodiments, the light source 12 may be an i-line, G-line, 248 nm, 193 nm, deep ultraviolet (DUV), sub-EUV, soft X-ray, or X-ray high source.

In various embodiments, the illuminator 14 includes various refractive optic components, such as a single lens or a lens system having multiple reflectors, for example lenses (zone plates) or alternatively reflective optics (for EUV lithography exposure system), such as a single mirror or a mirror system having multiple mirrors in order to direct light from the light source 12 onto the mask stage 16, particularly to a photomask 18 secured on the mask stage 16. In some embodiments, the light source 12 emits the EUV light 13. Then, the light 13 incident on the photomask 18. In embodiments in which the light source 12 generates light in the EUV wavelength range, reflective optics are employed. In some embodiments, the illuminator 14 includes at least two lenses, at least three lenses, or more.

The mask stage 16 is configured to secure the photomask 18. In some embodiments, the mask stage 16 includes an electrostatic chuck (e-chuck) to secure the photomask 18. One reason an e-chuck is beneficial is that gas molecules absorb EUV radiation and the e-chuck is operable in the lithography exposure system 10 for the EUV lithography patterning that is maintained in a vacuum environment to avoid EUV intensity loss. In the present disclosure, the terms mask, photomask, and reticle are used interchangeably. In the present embodiments, the photomask 18 is a reflective mask. One exemplary structure of the photomask 18 includes a substrate 18a with a suitable material, such as a low thermal expansion material (LTEM) or fused quartz. In various examples, the LTEM includes TiO₂ doped SiO₂, or other suitable materials with low thermal expansion. The photomask 18 includes a reflective multilayer deposited on the substrate 18a. The mask stage 16 is operable to translate in two horizontal directions, such as an X-axis direction and a Y-axis direction, so as to expose multiple different regions of the semiconductor wafer 22 to light 13′ having a pattern generated by the photomask 18. The semiconductor wafer 22 may have a mask layer thereon, which may be a photoresist layer 22b that is sensitive to the light 13′ carrying the pattern of the photomask 18.

The projection optics module (or projection optics box (POB)) 30 is configured for imaging the pattern of the photomask 18 on to the semiconductor wafer 22 secured on the substrate stage 24 of the lithography exposure system 10. In some embodiments, the POB 30 has refractive optics (such as for a UV lithography exposure system) or alternatively reflective optics (such as for an EUV lithography exposure system). The light 13′ directed from the photomask 18, carrying the image of the pattern defined on the photomask 18, is collected by the POB 30. The illuminator 14 and the POB 30 are collectively referred to as an optical module of the lithography exposure system 10.

In some embodiments, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium nitride (GaN), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate. In some other embodiments, the semiconductor wafer 22 may be glass, sapphire, printed wire board, polymer materials, or quasicrystal materials.

In addition, the semiconductor wafer 22 may have various circuit elements, semiconductor device elements, front-side interconnection structures, backside interconnection structures, and/or semiconductor devices over or in the front-side interconnection structures. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer 22 is coated with a photoresist layer 22b sensitive to the EUV radiation. Various components including those described above are integrated together and are operable to perform lithography processes.

The lithography exposure system 10 may further include other modules or be integrated with (or be coupled with) other modules, such as a cleaning module designed to provide hydrogen gas to the light source 12. The hydrogen gas helps reduce contamination in the light source 12.

In some embodiments, the photomask 18 used in the lithography exposure system 10 may be contaminated, for example, by the particle contaminants created from the lithography exposure system 10 or other factors. Therefore, the photomask 18 may be inspected regularly. However, the lithography exposure system 10 may stop the exposure processes once the photomask 18 is taken out of the lithography exposure system 10, which may extend the cycle time of the semiconductor wafers 22. On the other hand, the photomask 18 may be contaminated and thus transfers wrong patterns to the semiconductor wafers 22 if the photomask 18 is not under inspection in time. Therefore, the lithography exposure system 10 further includes a control device 100 configured to dynamically determine the safety state of the photomask 18 in use and dynamically determine if the semiconductor wafers 22 can go to the next process station without waiting for the mask inspections. Also, the control device 100 is configured to determine if the photomask 18 is qualified to be used in the lithography process to pattern the semiconductor wafer 22.

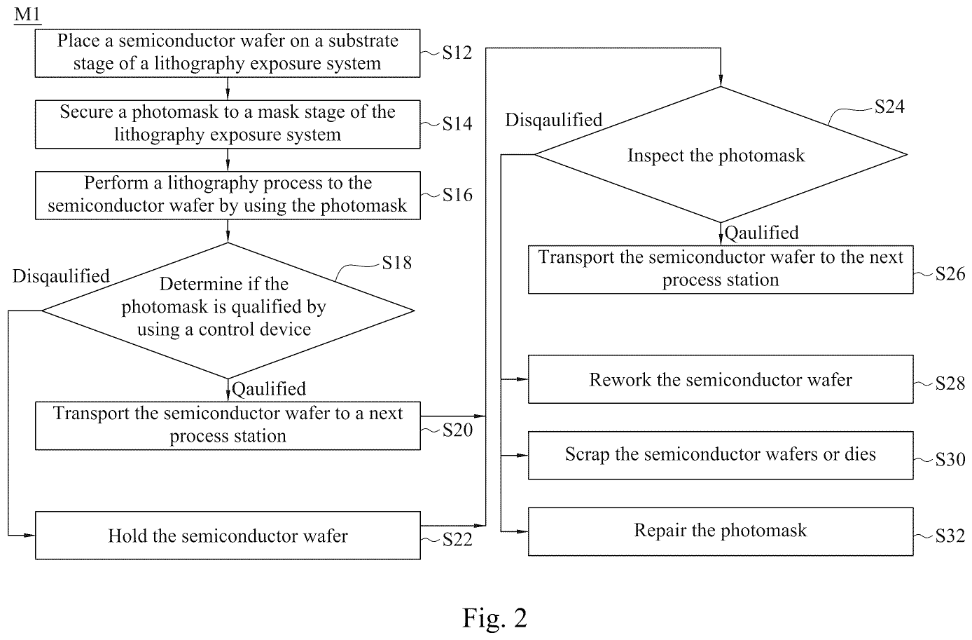

FIG. 2 is a flowchart illustrating a method M1 of lithography processes in accordance with some embodiments. Various operations of the method M1 are discussed in association with at least FIGS. 1 and 3-6. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified.

The operation S12 of the method M1 includes placing a semiconductor wafer on a substrate stage of a lithography exposure system. For example, as shown in FIG. 1, the semiconductor wafer 22 is placed on the substrate stage 24. The semiconductor wafer 22 may include a substrate 22a and a photoresist layer 22b over the substrate 22a. The photoresist layer 22b can be exposed by the lithography exposure system 10 and then patterned. The substrate 22a includes an object layer which inherits the pattern of the patterned photoresist layer 22b.

The operation S14 of the method M1 includes securing a photomask to a mask stage of the lithography exposure system. For example, as shown in FIG. 1, the photomask 18 is secured to the mask stage 16. In some embodiments, the photomask 18 may include a mask substrate 18a and a mask pattern 18b positioned over the mask substrate 18a. In some embodiments, the mask substrate 18a includes a transparent substrate, such as fused silica that is relatively free of defects, borosilicate glass, soda-lime glass, calcium fluoride, a low thermal expansion material, an ultra-low thermal expansion material, or other applicable materials. The mask pattern 18b may be positioned over the mask substrate 18a and may be designed according to the integrated circuit features or microstructures to be formed over a semiconductor wafer (e.g., the semiconductor wafer 22 of FIG. 1) during the lithography process. The mask pattern 18b may be formed by depositing a material layer (e.g., opaque materials such as metallic chromium) and patterning the material layer to have one or more openings where beams of radiation may travel through without being absorbed, and one or more absorption areas which may completely or partially block the beams of radiation. After the photomask 18 is secured to the mask stage 16, the mask pattern 18b faces the photoresist layer 22b of the semiconductor wafer 22.

The operation S16 of the method M1 includes performing a lithography process to the semiconductor wafer by using the photomask. For example, in FIG. 1, the light source 12 emits radiation (or light) 13, which is directed to the photomask 18 by the illuminator 14. The light 13 is then patterned by the mask pattern 18b of the photomask 18 and becomes the light 13′. The light 13′ is then directed from the photomask 18, carrying the image of the mask pattern 18b defined on the photomask 18, and is collected by the POB 30 and propagates to the photoresist layer 22b of the semiconductor wafer 22. Therefore, the photoresist layer 22b is patterned by the light 13′.

The operation S18 of the method M1 includes determining if the photomask is qualified by using a control device of the lithography exposure system. As mentioned above, the photomask 18 may be contaminated by particle contaminants and form defect(s) in the mask pattern 18b. The image of the defects may be transferred to the photoresist layer 22b, destroying the pattern of the photoresist layer 22b. Therefore, mask inspections are scheduled regularly to determine if the photomask 18 is qualified to be used continuously. However, the cycle time of the semiconductor wafers 22 may be extended if the exposed semiconductor wafers 22 wait for the mask inspection result. Therefore, in some embodiments, the control device 100 is configured to determine if the photomask 18 is under a safe (or a clean) state after the exposure process is performed to one or a wafer lot of semiconductor wafers 22. The semiconductor wafers 22 exposed by the qualified photomask 18 can be transported to the next process station without waiting for the mask inspection result (see operation S20).

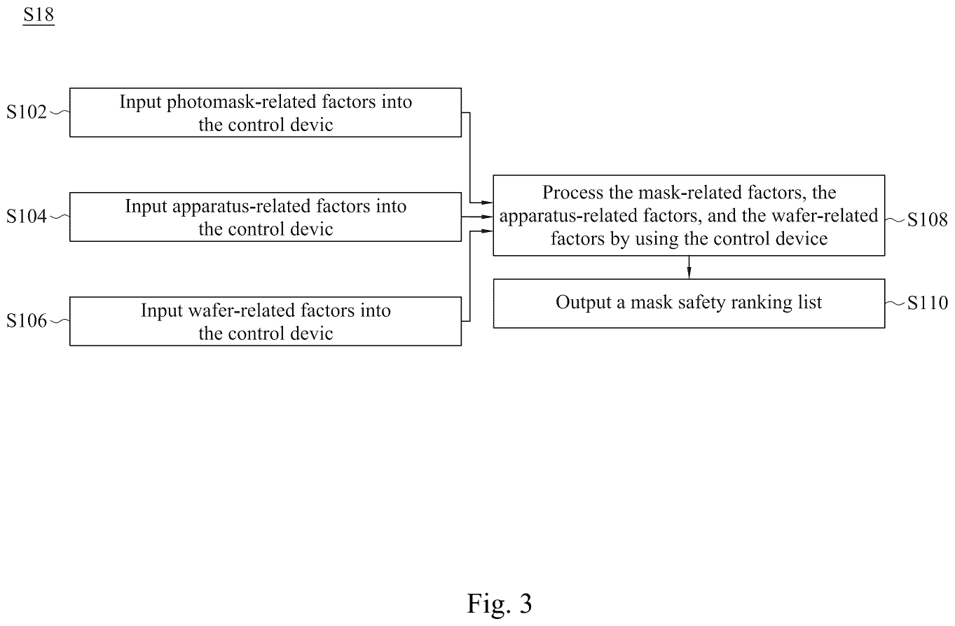

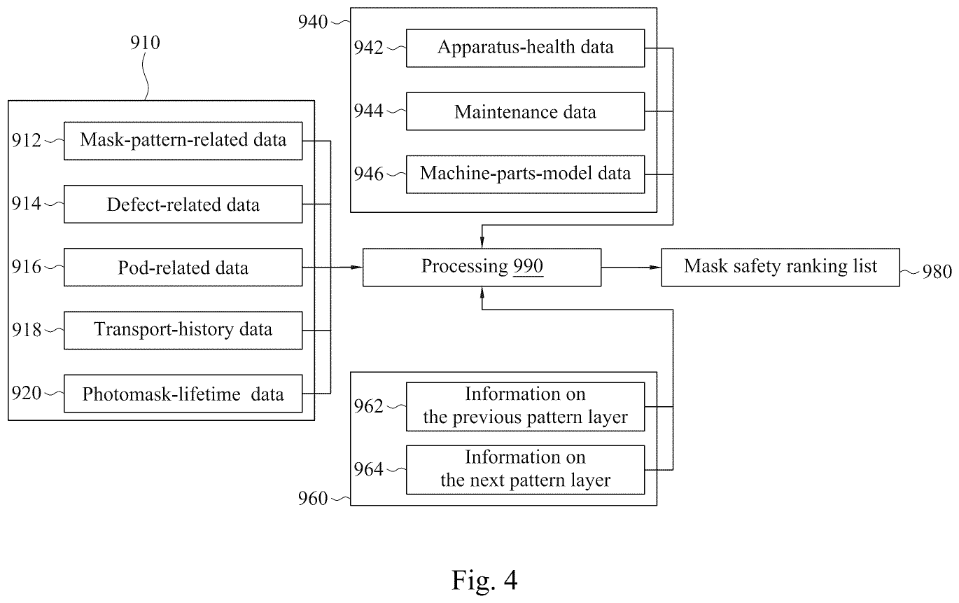

FIG. 3 is a flowchart illustrating the operation S18 of the method M1 of the lithography processes in accordance with some embodiments, and FIG. 4 is a process for operation S18 by using the control device 100 in accordance with some embodiments. Various operations of the operation S18 are discussed in association with at least FIGS. 1 and 5-6. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified.

The step S102 of the operation S18 includes inputting photomask-related factors into the control device. As shown in FIGS. 1 and 4, the photomask-related factors 910 may influence the safety of the photomasks 18. For example, the photomask-related factors 910 include mask-pattern-related data 912, defect-related data 914, pod-related data 916, transport-history data 918, photomask-lifetime data 920, and/or other data. Some or all of the data of the photomask-related factors 910 of the photomasks 18 in use and the candidate photomasks 18 can be input into the control device 100 to do the processing 990.

In some embodiments, the mask-pattern-related data 912 includes mask field utilization (MFU). The MFU is defined as: MFU=(mask utilized area)/(mask field area), where the photomask utilized area is an area of the features (for example, device pattern) of the photomask 18 to be transferred onto the semiconductor wafer 22 at one time. If the MFU is high, the particle contaminants may fall onto the mask pattern (or imaging area) at a high possibility, while the particle contaminants may fall onto the unutilized area of the photomask 18 if the MFU is low. Therefore, in some embodiments, as the MFU of the photomask 18 increases, the risk coefficient for particle contaminants falling onto the photomask 18 increases accordingly. For example, the photomasks 18 with low MFU have lower risk coefficients than the photomasks 18 with high MFU.

In some embodiments, the mask-pattern-related data 912 includes the density of mask pattern. If the density of mask pattern on the photomask 18 is high, the particle contaminants may fall onto the mask pattern 18b at a high possibility, while the particle contaminants may fall onto the unpatterned area of the photomask 18 if the pattern density on the photomask 18 is low. Therefore, in some embodiments, as the pattern density of the photomask 18 is denser, the risk coefficient for particle contaminants falling onto the photomask 18 increases accordingly. For example, the photomasks 18 with low pattern densities have lower risk coefficients than the photomasks with high pattern densities.

In some embodiments, the mask-pattern-related data 912 includes information of layers. Different photomasks 18 may include mask patterns corresponding to different layers of semiconductor devices. For example, the mask patterns 18b includes patterns at active region layers, patterns at gate structure layers, patterns at metal line layers, patterns at contact and/or contact via layers, or patterns at other layers. The complexity of the patterns depends on the information of the layers. Therefore, in some embodiments, as the complexity of the mask patterns of the photomask 18 increases, the risk coefficient for particle contaminants falling onto the photomask 18 increases accordingly.

In some embodiments, the mask-pattern-related data 912 includes number of die patterns. For example, a single photomask 18 may include one or more die patterns. That is, the photomask 18 includes one or more die patterns to be transferred onto the semiconductor wafer 22 at one time. For the photomasks 18 having a single die pattern, once the particle contaminant falls onto the photomask 18, the dies of whole semiconductor wafer 22 may all influenced. On the contrary, for the photomasks 18 having multiple die patterns, once the particle contaminant falls onto the photomask 18, it may occur that only one or two die patterns are influenced. Therefore, for the exposed semiconductor wafer 22, some of the dies inherit right patterns (corresponding to the die patterns that are not influenced by the defect), and some of the dies may inherit wrong patterns (corresponding to the die patterns that are influenced by the defect).

In some embodiments, the defect-related data 914 includes defect materials. The materials of the particle contaminants (or defects) may influence the safety of the photomasks 18. In greater details, some of the particle contaminants are translucent to the light 13. Therefore, even these kinds of particle contaminants are fall onto the photomask 18, the light 13 still transmits through the particle contaminants and the lithography results may be not influenced by the particle contaminants. The exposed semiconductor wafers 22 still inherit the right patterns. On the contrary, if the particle contaminants have materials that block the light 13, the exposed semiconductor wafers 22 may inherit the wrong patterns. In some embodiments, the particle contaminants are made of SiC, Sn, AlO, SiO, TiO, FeNi, NiO, PbO, and/or other elements produced from the machine parts and/or consumptive materials of the lithography exposure system 10.

In some embodiments, the defect-related data 914 includes the size of defects. The large-sized particle contaminant (or defect) may have a high possibility to block the mask pattern 18b, while the small-sized particle contaminant may fall onto the unpatterned area of the photomask 18. Therefore, in some embodiments, as the size of particle contaminants increases, the risk coefficient for particle contaminants falling onto the photomask 18 increases accordingly. For example, the photomasks 18 having small-sized particle contaminants have lower risk coefficients than the photomasks having large-sized particle contaminants.

In some embodiments, the defect-related data 914 includes the position of particle contaminants. The photomask 18 is safer when the particle contaminants fall onto the unpatterned area of the photomask 18 than when the particle contaminants fall onto the patterned area (or imaging area) of the photomask 18.

In some embodiments, the pod-related data 916 includes the cleaning schedule of the photomask pod. In greater detail, the photomask pod is a container configured to storing and transporting the photomask 18 when the photomask 18 is transported in the FAB. The particle contaminants may fall onto the photomask 18 from the photomask pod, and the photomask pod may generate particle contaminants or dusts if it is not cleaned too long. Therefore, the cleaning time point of the photomask pod may influence the cleanness of the photomask 18. In some embodiments, the risk coefficient for particle contaminants falling onto the photomask 18 increases if the photomask pod remains uncleaned for an extended period of time.

In some embodiments, the pod-related data 916 includes the type of the photomask pods. The photomask pod may include a base, a lid, seals or gaskets, latches or locking mechanisms, cushioning or support structures, labels, barcodes, and RFID tags. The base is configured to contain the photomask 18. In some embodiments, the base may include pins that support and fix the position of the photomask 18. The photomask 18 may be inclined in the base if the pins are damaged, and the particle contaminants may fall onto the photomask 18 more easily. Therefore, the mechanical structure of the photomask pod influences the risk coefficient for particle contaminants falling onto the photomask 18.

In some embodiments, the transport-history data 918 includes the number of times that the photomask is in and out of the lithography exposure system. The possibility of particle contaminants falling onto the photomask 18 increases as the number of times increases since the photomask 18 may be contaminated during the transportation of the photomask 18. In some embodiments, the transport-history data 918 includes the time period that the photomask is in the lithography exposure system. The possibility of particle contaminants falling onto the photomask 18 increases as the time period increases since the photomask 18 may be contaminated by the particle contaminants of the lithography exposure system 10. In some embodiments, the transport-history data 918 includes the radiation scanning rate of the exposure process. As the scanning rate of the light 13 increases, the dusts in the lithography exposure system 10 may move around more severely, and more particle contaminants may fall onto the photomask 18. In some embodiments, the transport-history data 918 includes the information of apparatuses and/or load ports where the photomask entered previously. The information of the apparatuses and/or load ports can be recorded in the control device 100. Once the photomask 18 previously enters the apparatuses and/or load ports which are damaged or have some issues, the photomask 18 can be marked by the control device 100 and the control device 100 may rank the photomask 18 down in the mask safety ranking list 980 (or rank them up in the risk coefficient ranking list).

In some embodiments, the photomask-lifetime data 920 includes the total pieces of exposed semiconductor wafer using the photomask after the previous mask inspection. In some embodiments, the photomask-lifetime data 920 includes the total pieces of exposed semiconductor wafer using the photomask since the photomask is produced. The photomask 18 may be aging and/or the particle contaminants may fall onto the photomask 18 if the photomask 18 is used to expose too many semiconductors wafers 22. In some embodiments, the photomask-lifetime data 920 includes the number of times of the mask inspections and the number of times of repairs after the photomask is produced. The photomask 18 may be aging if the photomask 18 experiences too many mask inspections and/or repairs. In some embodiments, the photomask-lifetime data 920 includes the time elapsed since the last repair of the photomask. The possibility of particle contaminants falling onto the photomask 18 increases as the time elapsed since the last repair of the photomask 18 increases.

The step S104 of the operation S18 includes inputting apparatus-related factors into the control device. As shown in FIGS. 1 and 4, the apparatus-related factors 940 may influence the safety of the photomasks 18. For example, the apparatus-related factors 940 include apparatus-health data 942, maintenance data 944, machine-parts-model data 946, and/or other factors. Some or all of the data of the apparatus-related factors 940 of the photomasks 18 in use and the candidate photomasks 18 can be input into the control device 100 to do the processing 990.

In some embodiments, the apparatus-health data 942 includes Statistical Process Control (SPC) data, Fault Detection Classification (FDC) data, Defect all on Frequency data, and/or other apparatus inspection or detection data. The health states of the apparatuses of the lithography exposure system 10 can be monitored and be input into the control device 100. If a specific apparatus has issues, the control device 100 may mark all the photomasks 18 entered in the specific apparatus and rank them down in the mask safety ranking list 980 (or rank them up in the risk coefficient ranking list).

In some embodiments, the maintenance data 944 includes last preventive maintenance times of the lithography exposure system 10. In some embodiments, the maintenance data 944 includes replacement dates of machine parts of the lithography exposure system. In some embodiments, the maintenance data 944 includes the actions the operators done in the previous maintenances. For example, except the elements shown in FIG. 1, the lithography exposure system 10 may further include reticle masking (ReMa) units, sliders, reticle stage short stroke modules, Uniformity Correction Module (UNICOM), and/or other machine parts. These parts may be replaced and/or regular maintenances are made regarding the lithography exposure system 10. After the replacements and/or the maintenances, these parts may cause less particle contaminants or dusts in the lithography exposure system 10, and the risk coefficient for particle contaminants falling onto the photomasks 18 may be decreased.

In some embodiments, the machine-parts-model data 946 includes model data of the machine parts of the lithography exposure system 10. The machine parts have their models, and the control device 100 may track the models. If a specific model of a specific machine part used in a specific apparatus has issues, the control device 100 may mark all the photomasks 18 used in the specific apparatus and rank them down in the mask safety ranking list 980 (or rank them up in the risk coefficient ranking list).

The step S106 of the operation S18 includes inputting wafer-related factors into the control device. As shown in FIGS. 1 and 4, the wafer-related factors 960 may influence the safety of the photomasks 18. For example, the wafer-related factors 960 include the information on the previous pattern layer 962, the information on the next pattern layer 964, and/or other factors. Some or all of the data of the wafer-related factors 960 of the photomasks 18 in use and the candidate photomasks 18 can be input into the control device 100 to do the processing 990.

In some embodiments, the information on the previous pattern layer 962 includes the health, apparatus, photomask, and/or other parameters used in a lithography process used to form the previous pattern layer, the manufacturing quality of the previous pattern layer, and/or other data. The previous pattern layer here means the pattern layer right down the photoresist layer 22b. That is, the previous pattern layer is the layer patterned by a lithography process before the deposition of the photoresist layer 22b and before the instant lithography process. In some embodiments, if the manufacturing quality of the previous pattern layer is not so good, the safety rank of the instant photomask 18 may be rank down, i.e., the safety standard of the instant photomask 18 may be raised to ensure the lithography quality. Further, the manufacturing quality of the previous pattern layer is related to the parameters used in the previous lithography process, such as the health, apparatus, photomask, and/or other parameters. Therefore, the parameters used in the previous lithography process can be input into the control device 100.

In some embodiments, the information on the next pattern layer 964 includes the health, apparatus, photomask, and/or other parameters used in a lithography process used to form the next pattern layer, the manufacturing quality of the next pattern layer, and/or other data. The next pattern layer here means the pattern layer formed right on a pattern layer patterned with the instant lithography process. In some embodiments, if the manufacturing quality of the next pattern layer is not so good, it is possible that the pattern layer patterned with the instant lithography process has some issues. Therefore, the manufacturing quality of the next pattern layer and the parameters of the corresponding lithography process may be input into the control device 100 and become factors to rank the instant photomask 18.

The step S108 of the operation S18 includes processing the mask-related factors, the apparatus-related factors, and the wafer-related factors by using the control device. As shown in FIG. 4, the control device 100 receives the data of the mask-related factors 910, the apparatus-related factors 940, and the wafer-related factors 960 related to the photomask 18 in use and candidates of photomasks 18 to do the processing 990, and the control device 100 is configured to rank the photomasks 18 in use and the candidate photomasks 18 according to the input data. In some embodiments, the criteria of the ranking are mentioned above, and, therefore, a description in this regard will not be repeated hereinafter. In some embodiments, the input data may be data in last six months. However, data in longer or shorter periods may be used in some other embodiments.

The step S110 of the operation S18 includes outputting a mask safety ranking list (and/or a risk coefficient ranking list). As shown in FIGS. 1 and 4, the control device 100 outputs a mask safety ranking list 980 according to the input data. The mask safety ranking list 980 includes photomasks 18 listed according to their risk coefficient for particle contaminants falling. The photomasks 18 with risk coefficients lower than a predetermined value can be regarded as qualified (or safety). On the contrary, the photomasks 18 with risk coefficients higher than a predetermined value can be regarded as disqualified (or unsafety). Reference is back to FIG. 2. With the mask safety ranking list 980, the control device 100 is able to determine whether the photomask 18 in use is qualified. Stated another way, the next action (transporting to a next process station or holding in the lithography exposure system 10) to the semiconductor wafers 22 is determined according to a determined result (i.e., qualified or disqualified in the mask safety ranking list) of the control device 100.

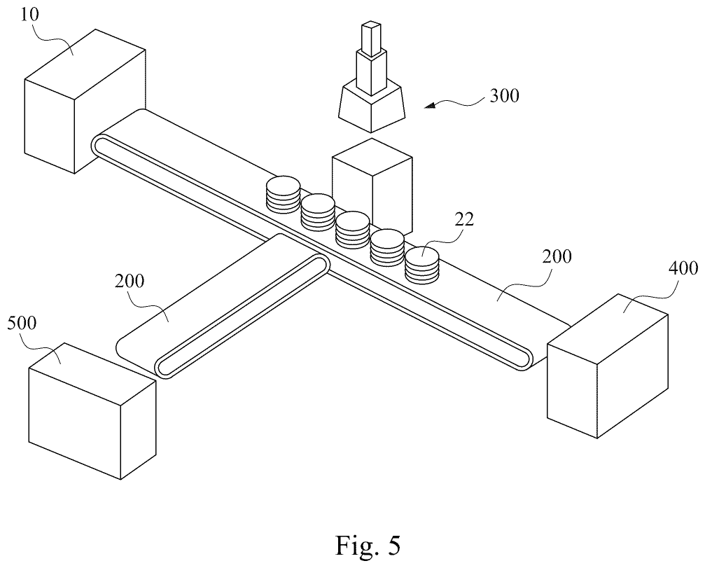

The operation S20 of the method M1 includes transporting the semiconductor wafer to a next process station when the photomask is qualified. FIG. 5 is an illustrative diagram of the lithography exposure system 10, a conveyer system 200, the semiconductor wafers 22, a mask inspection tool 300, and process stations 400 and 500 in accordance with some embodiments. In FIGS. 1 and 5, when the control device 100 determines the photomask 18 used to expose the semiconductor wafers 22 is qualified, the control device 100 then releases the semiconductor wafers 22 and transports the semiconductor wafers 22 to the next process station 400 by controlling the conveyer system 200. Therefore, the next process (e.g., an etching process for etching the photoresist layer 22b) can be performed to the semiconductor wafers 22 without waiting for the mask inspection, which may delay the cycle time of the manufacturing.

The operation S22 of the method M1 includes holding the semiconductor wafer when the photomask is disqualified. In FIGS. 1 and 5, when the control device 100 determines the photomask 18 used to expose the semiconductor wafers 22 is disqualified, the control device 100 then holds the semiconductor wafers 22 in the lithography exposure system 10. In this scenario, the semiconductor wafers 22 are held until the mask inspection result is released.

It is noted that, even the control device 100 determines that the photomask 18 is disqualified, the lithography process is still proceeding until a predetermined timing reaches. That is, the disqualified photomask 18 is still used to expose the next wafer lots of the semiconductor wafers 22 until the scheduled mask inspection timing comes. Therefore, the following exposed semiconductor wafers 22 are all held in the lithography exposure system 10 and wait for the mask inspection result.

The operation S24 of the method M1 includes inspecting the photomask. In FIGS. 1 and 5, when the predetermined timing comes, the photomask 18 is taken out of the lithography exposure system 10 to a mask inspection tool 300 to perform a mask inspection. In some embodiments, the mask inspection includes image data comparison, Auto Defect Calibration (ADC) image recognition, and/or other inspection processes. In some embodiments, the mask inspection tool 300 may include artificial intelligence modules.

In some embodiments, the predetermined time for mask inspection depends on cumulative pieces of semiconductor wafers 22. In greater detail, once the photomask 18 is secured to the mask stage 16, the photomask 18 is configured to expose a predetermined number of pieces of the semiconductor wafers 22 at most. Once the predetermined number of pieces of the semiconductor wafers 22 are exposed by using the photomask 18, the exposure process is stopped and the photomask 18 is taken out of the lithography exposure system 10 to perform the mask inspection.

However, in some scenario, the photomask 18 is taken out to perform the mask inspection even the number of pieces of the exposed semiconductor wafers 22 does not reach the predetermined value. For example, the predetermined time for mask inspection is related to wafer remaining quene time (Q-time), and/or high priority wafer remaining cycle time. In some embodiments, if the semiconductor wafers 22 are held (in operation S22), the cycle time of the semiconductor wafers 22 is extended. However, some semiconductor wafers 22 with high priority and/or short quene time can not wait too long. In these cases, the exposure process is stopped and the photomask 18 is taken out to perform the mask inspection.

In some other embodiments, the predetermined time for mask inspection is related to the holding time of the semiconductor wafers 22. For example, even the semiconductor wafers 22, which are held in the lithography exposure system 10, are not high priority and/or in a short quene time, the semiconductor wafers 22 are not desired to be held too long. Therefore, the photomask 18 is taken out to perform the mask inspection if the holding time of the semiconductor wafers 22 is longer than a predetermined period.

In some other embodiments, the predetermined time for mask inspection is related to risk exposure time. For example, the photomask 18 may experience a long exposure time while the photomask 18 is determined to be qualified after the manufacturing of many lots of the semiconductor wafers 22. Although the control device 100 determines that the photomask 18 is qualified so many times, the photomask 18 is still taken to perform the mask inspection when the exposure time is over the predetermined time.

In some other embodiments, the predetermined time for mask inspection is related to the capacity of mask inspection tools. For example, the mask inspections are scheduled so that the photomasks 18 having the mask inspection requirements are lined up to perform the mask inspection when the capacity of the mask inspection tools 300 is limited. With the control device 100, the requirements for mask inspection may be reduced and the timing for mask inspection may be more accurate. As such, the cost for the mask inspection tools 300 can be saved.

The operation S26 of the method M1 includes transporting the semiconductor wafer to the next process station when the photomask is qualified in the inspection result. As mentioned in the operation S22, the semiconductor wafers 22 are held in the lithography exposure system 10 when the control device 100 determines that the photomask 18 is disqualified. The held semiconductor wafers 22 are then transported to the next process station 400 by the control device 100 and the conveyer system 200 when the photomask 18 is qualified in the mask inspection result.

The operation S28 of the method M1 includes reworking the semiconductor wafer when the photomask is disqualified in the inspection result. As shown in FIGS. 1 and 5, when defect(s) is/are detected from the photomask 18 and/or the mask patterns of the photomask 18 goes wrong due to other reasons, the mask inspection result shows that the photomask 18 is disqualified. Therefore, the held semiconductor wafers 22 are transported to a process station 500 to remove the patterned photoresist layer 22b. After that, a new photoresist layer 22b is deposited over the substrate 22a, and a new lithography process is performed to the new photoresist layer 22b.

The operation S30 of the method M1 includes scrapping the semiconductor wafers or dies. In some other embodiments, the control device 100 determines that the photomask 18 is qualified (operation S20), but the mask inspection determines that the photomask 18 is disqualified. In these cases, the photoresist layers 22b of the semiconductor wafers 22 may have been etched, such that the semiconductor wafers 22 or the dies having wrong patterns are picked up and are scrapped. Even though, the scrap ratio is reduced with introducing the method M1.

The operation S32 of the method M1 includes repairing the photomask. The disqualified photomask 18, which is inspected in operation S24, is then transported to do the repair. The photomask 18 may be repaired and reused or may be scrapped depending on the extent of its damage.

Therefore, the lithography exposure system is able to manufacture the semiconductor wafers in an effective way. The input data (e.g., the photomask-related factors, the apparatus-related factors, and the wafer-related factors) can be input into the control device hourly or more frequently. As such, the mask safety ranking list reflects the safety of the photomasks almost in real time. Also, the suitable photomask may be determined among tens of thousands of machine-photomask combinations in just few minutes. Further, if any apparatus or wafer or photomask is detected to be damaged or failed, the control device can update the mask safety ranking list in a short time, and the photomasks related to the damaged apparatus or wafer or photomask can be tracked and be avoided to be used. In addition, the manpower can be reduced accordingly while the accuracy for usage of the photomask is raised. The cycle time for the manufacturing is also reduced and the productivity of the semiconductor wafers are gained.

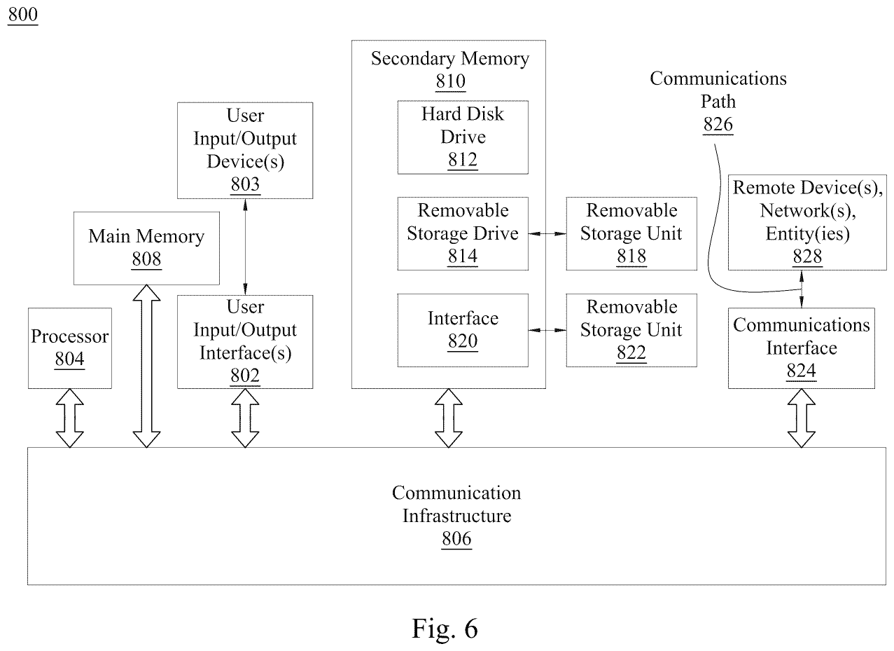

FIG. 6 a schematic diagram illustrating a computer system 800 in accordance with some embodiments of the present disclosure. In some embodiments, at least one of the control device 100 and the mask inspection tool 300 may be also known as a computer system 800. The computer system 800 may include artificial intelligence modules including XG boost module, machine learning module, big data mining module, decision tree module, and/or other suitable modules. As shown in FIG. 6, an illustration of an exemplary computer system 800 in which various embodiments of the present disclosure can be implemented, according to some embodiments. The computer system 800 may be used to do the processing 990 in FIG. 4 or the analyze for mask inspection. The computer system 800 may be any well-known computer capable of performing functions and operations described in the present disclosure. For example, and without limitation, the computer system 800 may be capable of processing and transmitting signals. The computer system 800 may be used, for example, to execute one or more functions of the lithography exposure system 10, which describes example operations of communications amongst different components therein.

The computer system 800 may include one or more processors (also called central processing units, or CPUs), such as a processor 804. The processor 804 is connected to a communication infrastructure or bus 806. The computer system 800 also includes input/output device(s) 803, such as monitors, keyboards, and pointing devices, that may communicate with communication infrastructure or bus 806 through input/output interface(s) 802. The computer system 800 may receive instructions to implement functions and operations described herein, e.g., functions of the control device 100 and mask inspection tool 300 and methods M1, via the input/output device(s) 803. The computer system 800 also includes a main or primary memory 808, such as random access memory (RAM). The main memory 808 may include one or more levels of cache. The main memory 808 has stored therein control logic (e.g., computer software) and/or data. In some embodiments, the control logic (e.g., computer software) and/or data may include one or more of the functions described with respect to the control device 100 and mask inspection tool 300.

The computer system 800 may also include one or more secondary storage devices or memory 810. The secondary memory 810 may include, for example, a hard disk drive 812 and/or a removable storage device or drive 814. Removable storage drive 814 can be a floppy disk drive, a magnetic tape drive, a compact disk drive, an optical storage device, tape backup device, and/or any other storage device/drive.

The removable storage drive 814 may interact with a removable storage unit 818. The removable storage unit 818 includes a computer usable or readable storage device having stored thereon computer software (control logic) and/or data. The removable storage unit 818 may be a floppy disk, magnetic tape, compact disk, DVD, optical storage disk, and/any other computer data storage device. The removable storage drive 814 reads from and/or writes to removable storage unit 818 in a well-known manner.

In some embodiments, the secondary memory 810 may include other means, instrumentalities or other approaches for allowing computer programs and/or other instructions and/or data to be accessed by the computer system 800. Such means, instrumentalities or other approaches can include, for example, a removable storage unit 822 and an interface 820. Examples of the removable storage unit 822 and the interface 820 may include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, the secondary memory 810, the removable storage unit 818, and/or the removable storage unit 822 may include one or more of the functions described with respect to the control device 100 and mask inspection tool 300.

The computer system 800 may further include a communication or network interface 824. The communication interface 824 enables the computer system 800 to communicate and interact with any combination of remote devices, remote networks, remote entities, etc. (individually and collectively referenced by reference number 828). For example, the communication interface 824 may allow the computer system 800 to communicate with the remote devices 828 over the communications path 826, which may be wired and/or wireless, and which may include any combination of LANs, WANs, the Internet, etc. Control logic and/or data may be transmitted to and from the computer system 800 via the communication path 826.

The functions and/or operations in the preceding embodiments may be implemented in a wide variety of configurations and architectures. Therefore, some or all of the operations in the preceding embodiments, e.g., functions of the control device 100 and mask inspection tool 300 and method M1, may be performed in hardware, in software or both. In some embodiments, a tangible apparatus or article of manufacture including a tangible computer useable or readable medium having control logic (software) stored thereon is also referred to herein as a computer program product or program storage device. This includes, but is not limited to, the computer system 800, the main memory 808, the secondary memory 810, and the removable storage units 818 and 822, as well as tangible articles of manufacture embodying any combination of the foregoing. Such control logic, when executed by one or more data processing devices (such as the computer system 800), causes such data processing devices to operate as described in the present disclosure. In some embodiments, the computer system 800 includes hardware/equipment for the manufacturing of photomasks and circuit fabrication. For example, the hardware/equipment may be connected to or be part of the element 828 (remote device(s), network(s), entity(ies)) of the computer system 800.

According to some embodiments, a method includes securing a photomask to a mask stage of a lithography exposure system. A lithography process is performed to a semiconductor wafer by using the photomask and the lithography exposure system. If the photomask is qualified is determined by a control device of the lithography exposure system. If the semiconductor wafer is transported to a next process station is determined according to a determined result of the control device.

According to some embodiments, a lithography exposure system includes a mask stage, a substrate stage, a light source, and a control device. The mask stage is configured to secure a photomask. The substrate stage is configured to secure a semiconductor wafer. The light source is configured to emit radiation to the photomask. The radiation patterned by the photomask is directed to the semiconductor wafer. The control device is configured to determine if the photomask is qualified to be used in a lithography process to pattern the semiconductor wafer.

According to some embodiments, a method includes performing an exposure process to a photoresist layer of a semiconductor wafer by using a photomask secured on a mask stage of a lithography exposure system. Parameters of the photomask are input into a control device of the lithography exposure system. A mask safety ranking list is output by the control device. Whether the semiconductor wafer is held in the lithography exposure system is determined according to the mask safety ranking list after the exposure process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
securing a photomask to a mask stage of a lithography exposure system;
performing a lithography process to a semiconductor wafer by using the photomask and the lithography exposure system;
determining if the photomask is qualified by a control device of the lithography exposure system; and
determining if the semiconductor wafer is transported to a next process station according to a determined result of the control device.

2. The method of claim 1, wherein determining if the semiconductor wafer is transported to the next process station comprises:
transporting the semiconductor wafer to the next process station when the control device determines that the photomask is qualified.

3. The method of claim 1, wherein determining if the semiconductor wafer is transported to the next process station comprises:
holding the semiconductor wafer in the lithography exposure system when the control device determines that the photomask is disqualified.

4. The method of claim 1, further comprising:
after determining if the semiconductor wafer is transported to the next process station, inspecting the photomask.

5. The method of claim 4, further comprising:
transporting the semiconductor wafers to the next process station when the photomask is qualified in the inspection.

6. The method of claim 4, further comprising:
reworking the semiconductor wafers when the photomask is disqualified in the inspection.

7. The method of claim 4, further comprising:
scrapping the semiconductor wafers when the photomask is disqualified in the inspection.

8. The method of claim 4, further comprising:
repairing the photomask when the photomask is disqualified in the inspection.

9. A lithography exposure system, comprising:
a mask stage configured to secure a photomask;
a substrate stage configured to secure a semiconductor wafer;
a light source configured to emit radiation to the photomask, wherein the radiation patterned by the photomask is directed to the semiconductor wafer; and
a control device configured to determine if the photomask is qualified to be used in a lithography process to pattern the semiconductor wafer.

10. The lithography exposure system of claim 9, wherein the operation of determining if the photomask is qualified comprises:
receiving input data related to the photomask in use and candidates of photomasks;
processing the input data; and
outputting a mask safety ranking list according to the input data.

11. The lithography exposure system of claim 10, wherein the input data comprises photomask-related factors comprising mask-pattern-related data, defect-related data, pod-related data, transport-history data, and photomask-lifetime data.

12. The lithography exposure system of claim 11, wherein the mask-pattern-related data comprising a mask field utilization, a density of mask pattern, information of layers, and a number of die patterns.

13. The lithography exposure system of claim 11, wherein the defect-related data comprises defect materials, a size of defects, and a position of particle contaminants.

14. The lithography exposure system of claim 11, wherein the pod-related data comprises a cleaning schedule of photomask pods and types of the photomask pods.

15. The lithography exposure system of claim 11, wherein the transport-history data comprises a number of times that the photomask is in and out of the lithography exposure system, a time period that the photomask is in the lithography exposure system, and a radiation scanning rate of an exposure process of the lithography process.

16. The lithography exposure system of claim 11, wherein the photomask-lifetime data comprises total pieces of exposed semiconductor wafers using the photomask, a number of times of mask inspections and a number of times of repairs after the photomask is produced, and a time elapsed since a last repair of the photomask.

17. The lithography exposure system of claim 10, wherein the input data comprises apparatus-related factors comprising apparatus-health data, maintenance data, and machine-parts-model data.

18. The lithography exposure system of claim 10, wherein the input data comprises wafer-related factors comprising information on a previous pattern layer of the semiconductor wafer, and information on a next pattern layer of the semiconductor wafer.

19. A method comprising:
performing an exposure process to a photoresist layer of a semiconductor wafer by using a photomask secured on a mask stage of a lithography exposure system;
inputting parameters of the photomask into a control device of the lithography exposure system;
outputting a mask safety ranking list by the control device; and
after the exposure process, determining whether the semiconductor wafer is held in the lithography exposure system according to the mask safety ranking list.

20. The method of claim 19, further comprising:
performing a mask inspection to the photomask after determining whether the semiconductor wafer is held in the lithography exposure system.
